(19) United States
(12) Patent Application Publication
(10) Pub. No.: US 2025/0086345 A1
(43) Pub. Date: Mar. 13, 2025

(54) COMBINATIONAL OPTIMIZATION OF SUPPORTS GIVEN DESIGN REQUIREMENTS

(71) Applicant: Bentley Systems, Incorporated, Exton, PA (US)

(72) Inventors: Dylan Wichman, Billings, MT (US); Stéphane Côté, Lac Beauport (CA)

(21) Appl. No.: 18/367,204

(22) Filed: Sep. 12, 2023

(51) Int. Cl. G06F 30/20

(52) U.S. Cl. CPC G06F 30/20

(57) ABSTRACT

In an example embodiment, software employs a combinational optimization algorithm to automatically add supports to an infrastructure model to both meet design requirements and minimize a criteria. The combinational optimization algorithm searches a massive search space while progressively reducing its size with valid solutions found by splitting the search space into a number of bins where each bin covers a different range of values of the criteria up to a maximum possible value, generating possible solutions for the bins, verifying possible solutions to ensure they satisfy design requirements, and updating the search space based on possible solutions by decreasing the maximum possible value based on valid solutions, and excluding tested invalid solutions from future generating. The process is repeated until a stopping condition is met yielding a final valid solution and supports are added to the infrastructure model of the types and at the locations indicated therein.

### BACKGROUND

### Technical Field

The present disclosure relates generally to infrastructure modeling, and more specifically to automated techniques for adding supports to an infrastructure model given design requirements.

### Background Information

The design of infrastructure (e.g., buildings, industrial plants, utility networks, etc.) is typically facilitated by infrastructure design and analysis software, with which a user (e.g., an engineer) may create an infrastructure model of the planned project. Some types of infrastructure may be composed of a number of interconnected members that are held in place at specific locations by supports. Depending on the type of infrastructure, the nature of the members and the supports may vary. For example, if the infrastructure is an industrial plant (e.g., an oil or gas plant, a nuclear plant, an offshore energy platform, a desalination plant, a thermo-solar plant, etc.) the members may be pipes that transport a relevant substance (e.g., oil, gas, water, steam, etc.) and the supports may be types of hangers (e.g., spring hangers, constant force hangers, etc.), restraints (e.g., v-stop restraints, incline restraints, line stop restraints, guide restraints, rotation restraints, damper restraints, etc.), links, etc. that each have different characteristics. Likewise, if the infrastructure is a commercial building, the members may be heating, ventilation, and air conditioning (HVAC) ducts that transport cooled or heated air and the supports may be types of HVAC duct straps, hangers, etc. that each have different characteristics. Similarly, if the infrastructure is a high tension electrical network, the members may be wires that conduct electricity and the supports may be types of cross arms, insulators, dampers, etc. that each have different characteristics.

Supports are required to resist various sustained, occasional, expansion and/or fatigue loads incident upon members. These design requirements may be codified in design codes (e.g., in the case of pipes, in American Society of Mechanical Engineers (ASME) B31.3, among others.). In addition to meeting such design requirements, it is typically also desired that supports minimize another criteria. The criteria may vary depending on the nature of the infrastructure. One possible criteria is cost. Alternatively, the criteria may be the total number of supports, the combined weight of the supports, the volume consumed by the supports, or some other quantity.

In complex infrastructure projects there are typically large numbers of possible locations along members where supports may be added, and large numbers of different types of supports that may be picked from. Further, in addition to using supports individually at locations, supports often can be combined into assemblies. In this context, an “assembly” refers to one or more supports combined or otherwise collocated together at the same location to collectively provide a supporting function. The result is that there are typically a huge number of possible permutations for locations and types of supports.

Traditionally, engineers have relied upon various “rules of thumb” to determine the locations and types of supports. While these “rules of thumb” may provide a solution that satisfies design requirements (e.g., design codes), such a solution is typically far from optimal in terms of minimizing criteria (e.g., cost, number, weight, volume, etc.).

More recently, attempts have been made to determine locations and types of supports using software that employs genetic algorithms. Genetic algorithms are inspired by Charles Darwin's theory of natural evolution and survival of the fittest. They start with an initial population of solutions that evolves though generations, inheriting from their parents. The weaker solutions are penalized, and the fitter solutions promoted so that they continue to evolve in further generations, until some stopping condition is met. One example use of generic algorithms is found in existing versions of the Support Optimizer of AutoPipe® design and analysis software, available from Bentley Systems, Inc.

While software that employs generic algorithms may determine solutions that are far more optimal than “rules of thumb”, it still suffers a number of shortcomings. Genetic algorithms often consume large amounts of processing and memory resources and often do not fully utilize the parallelism available on multi-core processors and cloud computing platforms. Because of this, software that employs generic algorithms may take hours to determine a believed-optimal solution for even a moderately sized infrastructure model. Further, the determined solution is often not truly the most optimal one, and the software typically lacks any ability to assure the user that the determined solution is optimal. A genetic algorithm may return a local minimum and be unaware that there is a better global minimum. Additionally, software that employs generic algorithms often requires users to set multiple hyperparameters that control the inner workings of the generic algorithms. User's whose training focuses on the design of infrastructure (e.g., civil engineers) often lack detailed knowledge of the inner workings of generic algorithms and may struggle to set appropriate hyperparameters. A poor choice of hyperparameters may impair the operation of generic algorithms, increasing already long processing times and increasing likelihood that a local rather than a global minimum is converged upon.

Accordingly, there is a need for improved techniques for adding supports (e.g., hangers, restraints, links, straps, cross-arms, insulators, dampers, etc.) along members (e.g., pipes, ducts, wires, etc.) in an infrastructure model that both meet design requirements (e.g., design codes) and minimizes a criteria (e.g., cost, number, weight, volume, etc.).

### SUMMARY

In various example embodiments, software employs a combinational optimization algorithm to automatically add supports (e.g., hangers, restraints, links, straps, cross-arms, insulators, dampers, etc.) along members (e.g., pipes, ducts, wires, etc.) to both meet design requirements (e.g., design codes) and minimize a criteria (e.g., cost, number, weight, volume, etc.). The software is able to efficiently search a massive search space while progressively reducing its size. The software may accomplish this by splitting the search space into a number of bins (e.g., defined by a Number of Bins hyperparameter), where each bin covers a different range of values of the criteria up to a maximum possible value of the criteria (e.g., defined by a Max Cost hyperparameter). Possible solutions may be sequentially generated for each of the bins, for example, using a random sampling algorithm to randomly place types of supports at possible locations until either a maximum number of locations are filled (e.g., defined by a Max Assemblies hyperparameter) or the value of the criteria reaches an upper limit of the range of values covered by the respective bin. Each possible solution may be verified to ensure it satisfies design requirements (e.g., design codes) and is thereby a valid solution. For valid solutions, the maximum possible value of the criteria (e.g., the Max Cost hyperparameter) may be decreased to a value no greater than the value of the criteria for the valid solution, and for invalid solutions they may be added to a set (e.g., a tree) of tested invalid solutions excluded from future solution generation. The process may be repeated, progressively narrowing the search space until a stopping condition is met (e.g., all possible solutions have either been tested or ruled out) yielding a final valid solution (e.g., the lowest cost solution).

Among other benefits, software that employs the combinational optimization algorithm may consume reduced processing and memory resources and take better advantage of parallelism, in comparison to prior approaches (e.g., approaches utilizing genetic algorithms). It may provide assurance that the final valid solution is the most optimal solution (i.e., the global minimum). Further, it may utilize hyperparameters (e.g., a Max Cost hyperparameter, a Number of Bins hyperparameter, and a Number of Assemblies hyperparameter) that are easily understood by users designing infrastructure (e.g., civil engineers), enabling them to better understand and control operations.

The improvements may be achieved in specific example embodiments. In one example embodiment, a method is provided for adding supports to an infrastructure model. Software that employs a combinational optimization algorithm executing on one or more computing devices determines a maximum possible value of a criteria for a solution and splits a search space into a number of bins based on the maximum possible value of the criteria, wherein each bin covers a different range of values of the criteria. It generates a possible solution for each of one or more of the bins that places one or more types of supports at one or more possible locations along members of the infrastructure model, wherein each possible solution has a value of the criteria that is within the range of values covered by the possible solution's respective bin. It further tests each possible solution to verify the possible solution satisfies design requirements and is thereby a valid solution, and updates the search space by, if the possible solution for a bin is a valid solution, decreasing the maximum possible value of the criteria to a value no greater than the value of the criteria for the valid solution, and, if the possible solution for the bin is not a valid solution, adding the possible solution for the bin to a set of tested invalid solutions excluded from future generating. It repeats the steps of splitting, generating, testing, and updating until a stopping condition is met and a final valid solution is returned, and adds supports of the types at the locations indicated by the final valid solution to the infrastructure model and outputs the infrastructure model.

In another example embodiment, a non-transitory computer readable medium having software encoded thereon is provided. The software when executed by one or more computing devices is operable to determine a maximum possible value of a criteria for a solution and split a search space into a number of bins based on the maximum possible value of the criteria, wherein each bin covers a different range of values of the criteria. The software is further operable to generate a possible solution for each of one or more bins that places one or more types of supports at one or more possible locations along members, wherein each possible solution has a value of the criteria that is within the range of values covered by the possible solution's respective bin. The software is also operable to test each possible solution to verify the possible solution satisfies design requirements and is thereby a valid solution, update the search space each time a possible solution for a bin is a valid solution by decreasing the maximum possible value of the criteria to a value no greater than the value of the criteria for the valid solution, continue to search the search space until an optimal solution that has a lowest value of the criteria is returned, and output an indication of the types of supports and the locations indicated by the optimal solution.

In another example embodiment, a computing device is provided that includes one or more processors and one or more memories coupled to the one or more processors, where the one or more memories are configured to store software that employs a combinational optimization algorithm. The software when executed on the one or more processors is operable to split a search space into a number of bins based on the maximum possible value of a criteria, wherein each bin covers a different range of values of the criteria, and generate a possible solution for each of one or more of the bins that places one or more types of supports at one or more possible locations along members of an infrastructure model, wherein each possible solution has a value of the criteria that is within the range of values covered by the possible solution's respective bin. The software is further operable to test each possible solution to verify the possible solution satisfies design requirements and is thereby a valid solution, and update the search space by decreasing the maximum possible value of the criteria based on valid solutions and excluding tested invalid solutions from future generating. The software is still further operable to continue to search the search space until a stopping condition is met, and a final valid solution is returned, and add supports of the types at the locations indicated by the final valid solution to the infrastructure model and output the infrastructure model.

It should be understood that a wide variety of additional features and alternative embodiments may be implemented other than those discussed in this Summary. This Summary is intended simply as a brief introduction to the reader for the further description that follows and does not indicate or imply that the examples mentioned herein cover all aspects of the disclosure or are necessary or essential aspects of the disclosure.

### BRIEF DESCRIPTION OF THE DRAWINGS

The description below refers to the accompanying drawings of example embodiments, of which:

FIG. 1 is a high-level block diagram of example software which may utilize a combinational optimization algorithm to automatically add supports (e.g., hangers, restraints, links, straps, cross-arms, insulators, dampers, etc.) along members (e.g., pipes, ducts, wires, etc.) in an infrastructure model to both meet design requirements (e.g., design codes) and minimize a criteria (e.g., cost, number, weight, volume, etc.);

FIG. 2 is a flow diagram of an example sequence of steps that may be executed by the software to automatically add supports (e.g., hangers, restraints, links, straps, cross-arms, insulators, dampers, etc.) along members (e.g., pipes, ducts, wires, etc.) in an infrastructure model;

FIG. 3 is a visualization of an example infrastructure model that may be shown in a user interface of the software, depicting user-selected possible locations supports along members; and

FIG. 4 is a chart comparing an example of operation of software that utilizes a combinational optimization algorithm with software that utilizes a genetic algorithm.

### DETAILED DESCRIPTION

The following detailed description describes example embodiments. Any references to items in the singular should be understood to include items in the plural, and vice versa, unless explicitly stated or otherwise clear from the context. Grammatical conjunctions are intended to express any and all disjunctive and conjunctive combinations of conjoined clauses, sentences, words, and the like, unless otherwise stated or clear from the context. For example, the term “or” should be understood to mean “and/or.” Any recitations of ranges of values are not intended to be limiting, are provided as examples only, and are not intended to constitute a limitation on the scope of the described embodiments. Further, any recitation of ranges should be interpreted as referring individually to any and all values falling within the range, unless otherwise indicated, and each separate value within such the range should be treated as if it were individually recited. Terms of approximation such as “about,” “approximately,” “substantially” or the like, should be construed as referring to an allowance for deviation that is appreciated by one of ordinary skill in the art. Terms of relative ordering or orientation, such as “first,” “last,” “greatest”, “lowest”, “top,” “bottom,” and the like, should be understood to be used relative to a standard of comparison or perspective, and do not preclude differing orderings or orientations based on different standards of comparison or perspectives. No language in the description should be construed as indicating an element is a necessary or essential aspect of the disclosure.

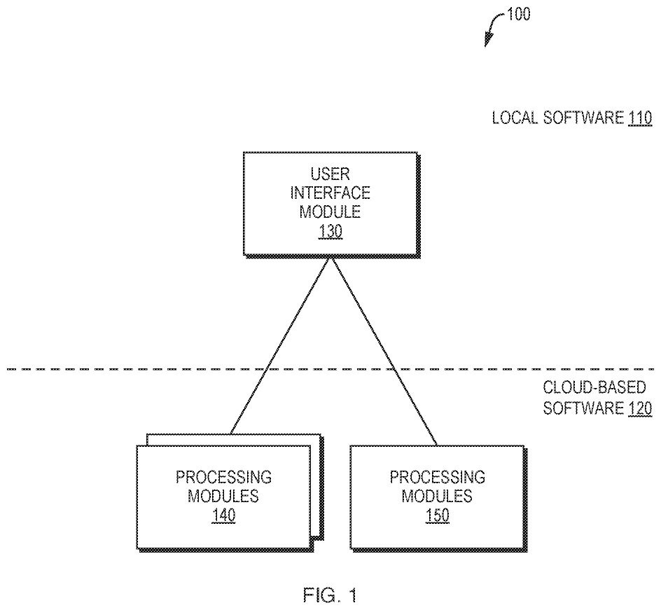

FIG. 1 is a high-level block diagram of example software which may utilize a combinational optimization algorithm to automatically add supports (e.g., hangers, restraints, links, straps, cross-arms, insulators, dampers, etc.) along members (e.g., pipes, ducts, wires, etc.) in an infrastructure model to both meet design requirements (e.g., design codes) and minimize a criteria (e.g., cost, number, weight, volume, etc.). In one embodiment, the application 100 is the AutoPipe® design and analysis software available from Bentley Systems, Inc. However, it should be understood that the application 100 may take a variety of other forms.

The software 100 may be executed on a single computing device. Alternatively, the application 100 may be divided into local software 110 executed on a computing device local to the user (a “local computing device”) and cloud-based software 120 that is executed on one or more computing devices remote from the user (collectively “cloud computing devices”) accessible via a network (e.g., the Internet). Each computing device may include one or more processors (e.g., multi-core processors) which support one or more threads. Each computing device may also include memory/storage, a display screen, and other hardware (not shown) for executing software, storing data and/or displaying information. The local software 110 may include a number of software modules operating on the local device and the cloud-based software 120 may include additional software modules operating on cloud computing devices. Tasks may be divided in a variety of different manners among the software modules. For example, software modules of the local software 110 may be responsible for performing non-resource intensive operations, such as providing user interface functionality. To that end, the software modules of the local software 110 may include a user interface module 130, as well as other software modules (not shown). The software modules of the cloud-based software 120 may be responsible for performing more resource intensive operations. To that end, the software modules of the cloud-based software 120 may include processing modules 140, as well as other software modules (not shown). In one embodiment, the software modules of the cloud-based software 120 may include a special type of processing module (a Support Optimizer module 150) that implements an improved Support Optimizer function that utilizes a combinational optimization algorithm to automatically add supports (e.g., hangers, restraints, links, straps, cross-arms, insulators, dampers, etc.) along members (e.g., pipes, ducts, wires, etc.) in an infrastructure model.

The combinational optimization algorithm may be roughly divided into configuration, optimization and validation operations. In the configuration operations, basic parameters of the optimization are set, for example, the possible locations along members of the infrastructure model for supports and values of hyperparameters. In the optimization operations, possible solutions are generated that represent different combinations of types of supports at different possible locations along the members of the infrastructure model with different values of the criteria. The search space is progressively reduced in size and the generated possible solutions focused on the remaining search space. The generation of individual possible solutions may consume relatively small amounts of processing and memory resources. In the validation operations, possible solutions are tested to verify they satisfy design requirements (e.g., design codes) and thereby are valid solutions. The testing may be performed by submitting each possible solution to an instance of design and analysis software that determines if the proposed types of supports at the proposed locations sufficiently support the members. The testing of individual possible solutions may consume relatively large amounts of processing and memory resources. However, as a result of progressively narrowing the search space, the number of tests that need to be performed may be limited. By limiting the need for resource intensive testing, the overall processing and memory usage may be reduced in comparison to prior approaches.

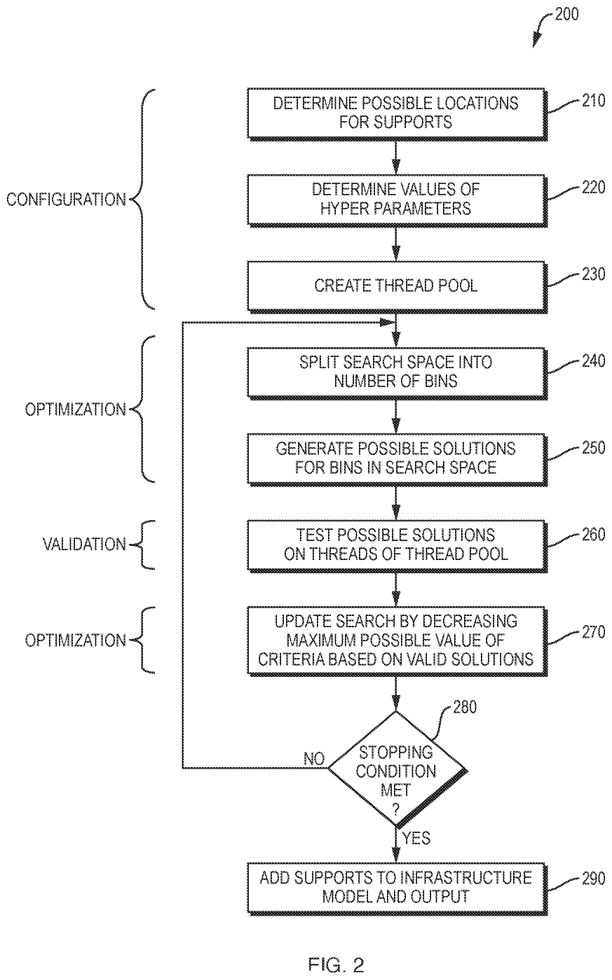

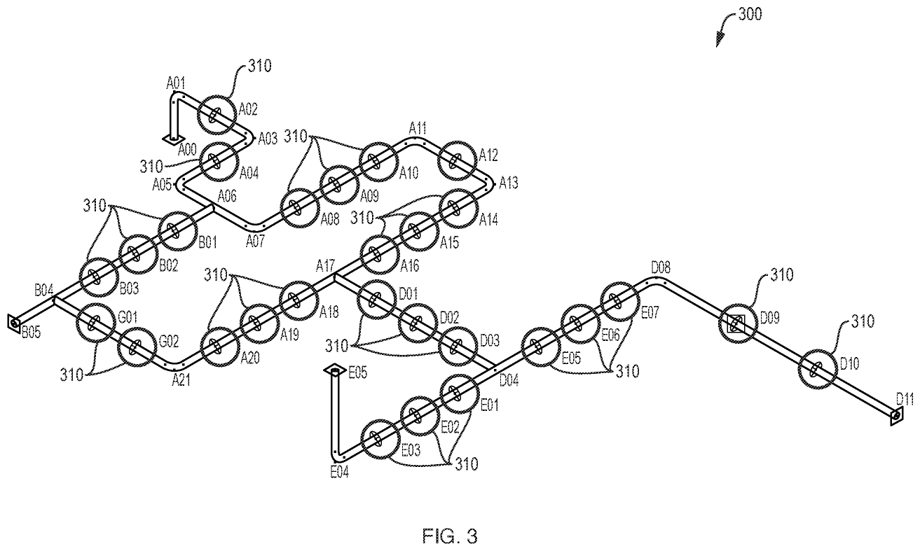

FIG. 2 is a flow diagram of an example sequence of steps 200 that may be executed by the software 100 (or more specifically the Support Optimizer module 150) to automatically add supports (e.g., hangers, restraints, links, straps, cross-arms, insulators, dampers, etc.) along members (e.g., pipes, ducts, wires, etc.) in an infrastructure model. As part of the configuration operations, at step 210, the software 100 determines possible locations for supports along members of the infrastructure model. In one embodiment, the possible locations may be determined based on user selections of locations along members. Alternatively, locations may be automatically determined by an algorithm. FIG. 3 is a visualization 300 of an example infrastructure model that may be shown in a user interface of the software 100, depicting user-selected possible locations for supports along members. The user may have clicked on or otherwise marked each location to select it.

As a further part of the configuration operations, at step 220, the software 100 determines values of hyperparameters. The values may be default values. Alternatively, the user may provide custom values of one or more of the hyperparameter in a user interface of the software 100.

The hyperparameters may include a first hyperparameter (e.g., a Max Cost hyperparameter) that defines the maximum possible value of the criteria up to which the software will generate possible solutions. For example, if the criteria is cost, the first hyperparameter (e.g., the Max Cost hyperparameter) may be set to a monetary value (e.g., $100,000) and the software 100 may generate possible solutions that cost less than the value (e.g., use supports whose total cost is less than $100,000). An appropriate value for the first hyperparameter (e.g., the Max Cost hyperparameter) may be intuitively known by users (e.g., engineers), who often have a sense of an appropriate value based on their past experience. If the user does not select a value, a default value of the first hyperparameter (e.g., the Max Cost hyperparameter) may be determined, for example, by taking a sum of the highest value (e.g., highest cost) supports that could be placed at each possible location.

The hyperparameters may also include a second hyperparameter (e.g., a Number of Bins hyperparameter) that defines the number of bins (or parts) the software 100 will split the search space into. The second hyperparameter (e.g., the Number of Bins hyperparameter) often may not be changed from a default value (e.g., 5), unless a user (e.g., engineer) has a good understanding of how the combinational optimization algorithm operates.

The hyperparameters may also include a third hyperparameter (e.g., a Number of Assemblies hyperparameter) that defines a maximum number of assemblies that may be used when the software 100 generates possible solutions. For example, if the third hyperparameter (e.g., the Number of Assemblies hyperparameter) is set to a given number (e.g., 10), the software 100 may place supports at up to the given number of locations (e.g., up to 10 location) along members so that there are no more than the given number of (e.g., 10) assemblies used in generated solutions. A maximum number of assemblies may be intuitive to users (e.g., engineers), who often may have a general sense of how many assemblies will be required based on their past experience.

As part of the configuration operations, at step 230 the software 100 creates a thread pool with a number of threads. If the software 100 is being executed on a single computing device, the number of threads may be a number of cores on the processor(s) of such machine. If the software 100 is being executed in a distributed manner, with processing performed in the cloud on one or more cloud computing devices, the number of threads may be massive, encompassing cores or virtual units on many machines.

As part of the optimization operations, at step 240, the software 100 splits the search space into a number of bins (e.g., defined by the Number of Bins hyperparameter), where each bin covers a different range of values of the criteria up to a maximum possible value of the criteria (e.g., defined by the Max Cost hyperparameter). For example, if the criteria is cost, the Number of Bins hyperparameter is set to 5, and the Max Cost hyperparameter is set to $100,000, the software 100 may initially split the search space into ranges of [$0-$20,000], [$20,000-$40,000], [$40,000-$60,000], [$60,000-$80,000] and [$80,000-$100,000].

As a further part of the optimization operations, at step 250, the software 100 sequentially generates possible solutions for the bins that place one or more types of supports at one or more possible locations along members of the infrastructure model, wherein each possible solution has a value of the criteria that is within the range of values covered by the possible solution's respective bin. In one embodiment, the software uses a random sampling algorithm to randomly place types of supports at possible locations until either a maximum number of locations are filled (e.g., defined by the Max Assemblies hyperparameter) or the value of the criteria reaches an upper limit of the range of values covered by the respective bin. For example, if the criteria is cost and the Max Assemblies hyperparameter is 10, for a bin [$0-$20,000] the random sampling algorithm may randomly place types of supports at up to 10 locations along members until their total cost reaches the upper bin limit of $20,000, or the remaining cost before the limit is insufficient for even a cheapest support (e.g., there is only $200 remaining, but the cheapest support is $500). The random sampling algorithm may repeat this process sequentially to create random combinations for each of the bins.

As part of the verification operations, at step 260, the software 100 tests each possible solution generated in step 250 to verify the possible solution satisfies design requirements (e.g., design codes) and is thereby a valid solution. The testing may be performed by executing an instance of design and analysis software (e.g., AutoPipe® design and analysis software) on each of the threads of the thread pool and submitting each possible solution to a different instance. The instance may simulate the possible solution to determine if the proposed types of supports at the proposed locations sufficiently support the members to resist the various sustained, occasional, expansion and/or fatigue loads incident upon members of the infrastructure and may return an indication that the possible solution is a valid solution if they do, or is an invalid solution if they do not. For example, in a case where the criteria is cost and the search space is split into 5 bins of ranges of [$0-$20,000], [$20,000-$40,000], [$40,000-$60,000], [$60,000-$80,000] and [$80,000-$100,000], the possible solutions for the [$20,000-$40,000]. [$40,000-$60,000], and [$80,000-$100,000] bins may be determined to be valid solutions and the possible solutions for the [$0-$20,000] and [$60,000-$80,000] bins may be determined to be invalid solutions.

As a further part of the optimization operations, at step 270, the software 100 updates the search space by decreasing the maximum possible value of the criteria based on valid solutions and excludes tested invalid solutions from future possible solution generation. Specifically, if a possible solution for a bin is a valid solution, the software 100 may decrease the maximum possible value of the criteria to a value no greater than the value of the criteria for the valid solution. For example, continuing the above example where the criteria is cost, for a valid possible solution of $39,200 for a [$20,000-$40,000] bin, the software may decrease the Max Cost hyperparameter initially set at $100,000 to be no greater than $39,200. By narrowing the search space in this manner, the amount of processing and memory resources intensive verification operations needed may be reduced. It may be noted that once set to $39,200, a valid possible solution for a [$40,000-$60,000] bin may have no effect on the Max Cost hyperparameter, as it will necessarily be greater than the current maximum.

Likewise, if the possible solution for the bin is not a valid solution, the software 100 may exclude the invalid solution from future possible solution generation by adding it to a set of tested invalid solutions (e.g., an invalid solution tree). Each time a solution is subsequently generated for a bin, it may be tested against the set of tested invalid solutions (e.g., the invalid solution tree). If found therein, the generated solution may be discarded and a new solution generated for the bin, provided there are remaining untested possible solutions for the range of values of the criteria covered by the respective bin. For instance, continuing the above example where the criteria is cost, the invalid possible solution found for the [$0-$20,000] may be added to the invalid solution tree, such that each time a solution is subsequently generated it may be excluded. By excluding already tested invalid solutions, expenditure of processing and memory resources on duplicative testing may be avoided.

At step 280, Execution may loop to step 240, and the optimization and verification operations of steps 240-270 repeated until a stopping condition is met and a final valid solution is returned. The stopping condition may be an indication that the final valid solution is an optimal solution (e.g., a global minimum) that has a lowest value of the criteria. In one embodiment, this may be determined by comparing the number of remaining possible solutions (e.g., the number of permutations that cost less than the Max Cost hyperparameter) to the number of invalid solutions in the set of tested invalid solutions (e.g., the invalid solution tree) that have a lesser value of the criteria than the present solution. If these numbers are equal, it means that all possible solutions have been tested or ruled out as less optimal. Consequently, it can be assured that the present solution is the optimal solution with a lowest value of the criteria.

The stopping condition may alternatively be user input indicating processing should terminate, expiration of a timer or counter, crossing a threshold for the value of the criteria, or other trigger. In such cases, the final valid solution may not necessarily be an optimal solution (e.g., a global minimum), but may be a “good enough” solution that satisfies practical constraints.

At step 290, the software 100 adds supports of the types at the locations indicated by the final valid solution (e.g., the optimal solution) to the infrastructure model and outputs the infrastructure model (e.g., by displaying some or all of the infrastructure model with the added supports in the user interface of the software 100, by storing the infrastructure model with the added supports to memory/storage, by transmitting the infrastructure model with the added supports to another computing device, etc.). Using this output, infrastructure may be constructed that includes supports of the types at the locations indicated by final valid solution (e.g., the optimal solution), yielding an improved (e.g., optimal) structure in the physical world.

In summary, software 100 may be improved by using a combinational optimization algorithm to automatically add supports (e.g., hangers, restraints, links, straps, cross-arms, insulators, dampers, etc.) along members (e.g., pipes, ducts, wires, etc.) to both meet design requirements (e.g., design codes) and minimize a criteria (e.g., cost, number, weight, volume, etc.). Numerous benefits may be achieved. As mentioned above, processing and memory resource consumption may be reduced in comparison to prior approaches (e.g., approaches utilizing genetic algorithms), assurance may be gained that an optimal solution (a global minimum) has been found, and more intelligible hyperparameters may be used, in comparison to prior approaches (e.g., approaches utilizing genetic algorithms).

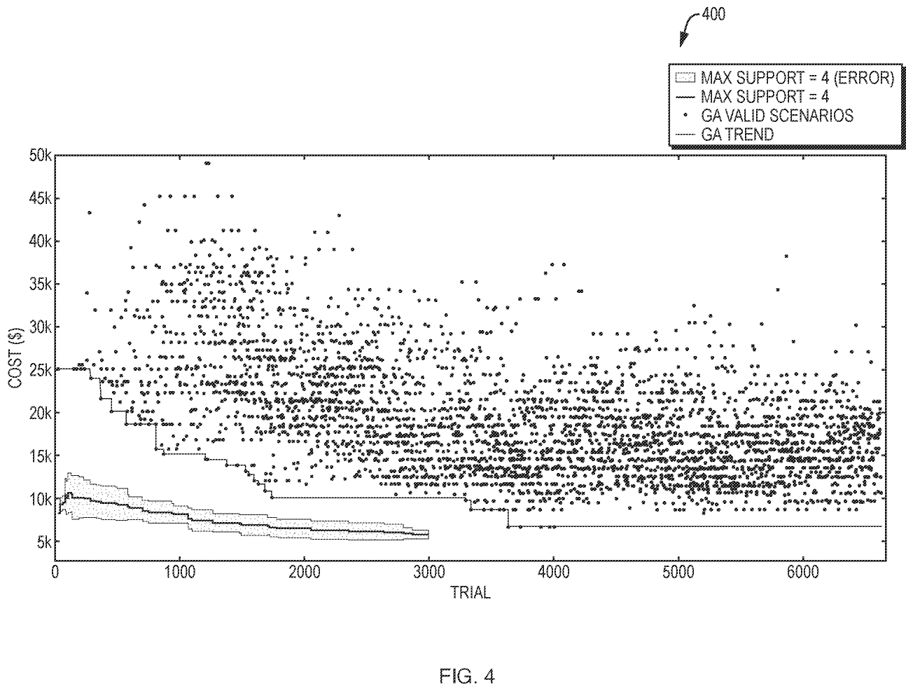

FIG. 4 is a chart 400 comparing an example of operation of software 100 that utilizes a combinational optimization algorithm with software that utilizes a genetic algorithm. In this example, the value of a criteria (here, cost) for a valid solution is plotted against a number of solutions tested (referred to here as “trials”). As can be seen, the software 100 that utilizes the combinational optimization algorithm arrives at a lower cost solution using fewer tests, providing improved results while also consuming reduced processing and memory resources. Further, the user may be assured the solution arrived at is the optimal solution (a global minimum), and not merely a local minimum (like the one converged to in this example by the software that utilizes the genetic algorithm).

While it is discussed above that functionality may be implemented by specific software executing on specific hardware, it should be understood that the functionality may also be implemented by different software, different hardware, or various different combinations thereof. Software may include instructions in a high-level programming language or low-level programming language that may be stored and compiled or interpreted to run on hardware. For example, instructions may be stored on a non-transitory electronic device readable medium and when executed on one or more processors may be operable to implement the functionality.

It should be understood that the ordering of any method steps discussed above may be changed to suit various situations or requirements. Absent an explicit indication to the contrary, the order of steps described above may be modified such that a subsequent step occurs before a preceding step, or in parallel to such step.

Above all, it should be understood that the above descriptions are meant to be taken only by way of example. Numerous variations, additions, omissions, and other modifications will be apparent to one of ordinary skill in the art, and such variations, additions, omissions, and other modifications should be considered within the scope of this disclosure. Thus, while example embodiments are shown and described, it will be apparent to those skilled in the art that changes and modifications may be made therein without departing from the spirit and scope of this disclosure.

What is claimed is:

1. A method for adding supports to an infrastructure model, comprising:
determining a maximum possible value of a criteria for a solution;
splitting, by software that employs a combinational optimization algorithm executing on one or more computing devices, a search space into a number of bins based on the maximum possible value of the criteria, wherein each bin covers a different range of values of the criteria;
generating, by the software, a possible solution for each of one or more of the bins that places one or more types of supports at one or more possible locations along members of the infrastructure model, wherein each possible solution has a value of the criteria that is within the range of values covered by the possible solution's respective bin;
testing, by the software, each possible solution to verify the possible solution satisfies design requirements and is thereby a valid solution;
updating, by the software, the search space by
if the possible solution for a bin is a valid solution, decreasing the maximum possible value of the criteria to a value no greater than the value of the criteria for the valid solution, and
if the possible solution for the bin is not a valid solution, adding the possible solution for the bin to a set of tested invalid solutions excluded from future generating;
repeating the steps of splitting, generating, testing, and updating until a stopping condition is met and a final valid solution is returned; and
adding, by the software, supports of the types at the locations indicated by the final valid solution to the infrastructure model and outputting the infrastructure model.

2. The method of claim 1, wherein the final valid solution is an optimal solution that has a lowest value of the criteria, and the stopping condition is that remaining possible solutions have been included in the set of tested invalid solutions.

3. The method of claim 1, wherein the determining comprises:
receiving the maximum possible value of the criteria as a user-provided hyperparameter.

4. The method of claim 1, further comprising:
receiving the number of bins as a user-provided hyperparameter.

5. The method of claim 1, further comprising:
receiving a maximum number of assemblies as a user-provided hyperparameter,
wherein the generating generates possible solutions that place one or more types of supports at a number of locations along members that does not exceed the maximum number of assemblies.

6. The method of claim 1, wherein the generating further comprises:
using a random sampling algorithm to randomly place the one or more types of supports at the one or more possible locations until either a maximum number of locations are filled, or the value of the criteria reaches an upper limit of the range of values covered by respective bin.

7. The method of claim 1, wherein the testing further comprises:
sending the possible solution for each bin to a thread of thread pool, wherein each thread uses an instance of design and analysis software to verify the respective possible solution.

8. The method of claim 1, wherein the criteria is cost, and the final valid solution is a lowest cost solution.

9. The method of claim 1, wherein the member is a pipe and the types of supports include hangers, restraints or links for pipes.

10. The method of claim 1 further comprising constructing infrastructure based on the infrastructure model that includes supports of the types at the locations indicated by the final valid solution.

11. A non-transitory computer readable medium having software encoded thereon, the software when executed by one or more computing devices operable to:
determine a maximum possible value of a criteria for a solution;
split a search space into a number of bins based on the maximum possible value of the criteria, wherein each bin covers a different range of values of the criteria;
generate a possible solution for each of one or more of the bins that places one or more types of supports at one or more possible locations along members, wherein each possible solution has a value of the criteria that is within the range of values covered by the possible solution's respective bin;
test each possible solution to verify the possible solution satisfies design requirements and is thereby a valid solution;
update the search space when a possible solution for a bin is a valid solution by decreasing the maximum possible value of the criteria to a value no greater than the value of the criteria for the valid solution;
continuing to search the search space until a final valid solution is returned;
outputting an indication of the types of supports and the locations indicated by the final valid solution.

12. The non-transitory computer readable medium of claim 11, wherein the software when executed is further operable to:
update the search space when a possible solution for a bin is an invalid solution by adding the possible solution for the bin to a set of tested invalid solutions excluded from future generation.

13. The non-transitory computer readable medium of claim 11, wherein the software when executed is further operable to:
receive the maximum possible value of the criteria as a user-provided hyperparameter.

14. The non-transitory computer readable medium of claim 11, wherein the software when executed is operable to:
receive the number of bins as a user-provided hyperparameter.

15. The non-transitory computer readable medium of claim 11, wherein the software when executed is operable to:
receive a maximum number of assemblies as a user-provided hyperparameter,
wherein the possible solutions place one or more types of supports at a number of locations along members that does not exceed the maximum number of assemblies.

16. The non-transitory computer readable medium of claim 11, wherein the software when executed is operable to:
use a random sampling algorithm to randomly place the one or more types of supports at the one or more possible locations until either a maximum number of locations are filled, or the value of the criteria reaches an upper limit of the range of values covered by respective bin.

17. The non-transitory computer readable medium of claim 11, wherein the criteria is cost, and the final valid solution is a lowest cost solution.

18. The non-transitory computer readable medium of claim 11, wherein the member is a pipe and the types of supports include hangers, restraints or links for pipes.

19. A computing device, comprising:
one or more processors; and
one or more memories coupled to the one or more processors, the one or more memories configured to store software that employs a combinational optimization algorithm, wherein the software when executed on the one or more processors is operable to:
split a search space into a number of bins, wherein each bin covers a different range of values of a criteria,
generating a possible solution for each of one or more of the bins that places one or more types of supports at one or more possible locations along members of an infrastructure model, wherein each possible solution has a value of the criteria that is within the range of values covered by the possible solution's respective bin,
test each possible solution to verify the possible solution satisfies design requirements and is thereby a valid solution,
update the search space by
decreasing the maximum possible value of the criteria based on valid solutions, and
excluding tested invalid solutions from future generating,
continue to search the search space until a stopping condition is met, and a final valid solution is returned;
add supports of the types at the locations indicated by the final valid solution to the infrastructure model and output the infrastructure model.

20. The computing device of claim 19, wherein the criteria is cost, the member is a pipe and the types of supports include hangers, restraints or links for pipes.
